(19) United States
(12) Patent Application Publication
(10) Pub. No.: US 2015/0228462 A1
(43) Pub. Date: Aug. 13, 2015

(54) PLASMA PROCESSING APPARATUS

(71) Applicant: TOKYO ELECTRON LIMITED, Tokyo (JP)

(72) Inventors: Akihiro Yoshimura, Miyagi (JP); Yasushi Masuda, Miyagi (JP); Nobutaka Sasaki, Miyagi (JP)

(73) Assignee: TOKYO ELECTRON LIMITED, Tokyo (JP)

(21) Appl. No.: 14/426,852

(22) PCT Filed: Sep. 11, 2013
(86) PCT No.: PCT/JP2013/074538

§ 371 Date: Mar. 9, 2015

Related U.S. Application Data
(60) Provisional application No. 61/703,945, filed on Sep. 21, 2012.

(30) Foreign Application Priority Data
Sep. 13, 2012 (JP) 2012-201824

(51) Int. Cl. H01J 37/32

(52) U.S. Cl. CPC H01J 37/32834; H01J 37/32458; H01J 37/32532; H01J 37/32633; H01J 37/32715; H01J 37/32733

(57) ABSTRACT

In a plasma processing apparatus, a partition wall connects a mounting table and a bottom wall of a processing chamber. A power feed member is disposed within the space surrounded by the partition wall and connected to the mounting table. A driving frame extends into the space surrounded by the partition wall from the outside of the sidewall of the processing chamber to be connected to the bottom of the mounting table. A driving mechanism is disposed to the outside of the processing chamber to move the driving frame vertically. At the bottom of a gas exhaust space, an annular gas exhaust passageway is defined by the partition wall and the sidewall and bottom wall of the processing chamber. The gas exhaust unit is interconnected to the gas exhaust passageway through a gas exhaust port at the bottom wall of the processing chamber.

### FIELD OF THE INVENTION

The present invention relates to a plasma processing apparatus.

### BACKGROUND OF THE INVENTION

Conventionally, as for a plasma processing apparatus, there is known an apparatus including: a processing chamber that defines therein a processing space; a mounting table, provided at a lower portion of the processing chamber, for mounting thereon a target object, the mounting table also serving as a lower electrode; an upper electrode provided at an upper portion of the processing chamber; and a gas exhaust unit for depressurizing the processing space (see, e.g., Japanese Patent Application Publication No. 2004-63925). In this apparatus, the processing space, the mounting table and the gas exhaust unit are coaxially arranged to improve distribution of flow of reactant gas.

The apparatus disclosed in Japanese Patent Application Publication No. 2004-63925 includes an elevation driving mechanism for vertically moving the mounting table. A distance (hereinafter, may be referred to as “gap”) of the processing space between the upper electrode and the lower electrode can be controlled by vertically moving the mounting table. The elevation driving mechanism includes a driving motor, a power transmission unit such as a gear or the like for transmitting power of the driving motor to a ball screw, a moving unit driven together with the mounting table by rotation of the ball screw. The driving motor is provided near the side portion of the mounting table at the outside of the processing chamber. The power transmission unit and the moving unit are provided inside the processing chamber, i.e., inside a gas exhaust passageway.

However, in the apparatus disclosed in Japanese Patent Application Publication No. 2004-63925, the driving transmission unit and the moving unit provided inside the gas exhaust passageway may disturb the flow of the reactant gas. Therefore, the evacuation may become non-uniform and this may result in non-uniform plasma processing. Hence, the uniformity of the evacuation in the apparatus having a gap adjusting unit needs to be improved.

In order to realize uniform plasma processing, a power feed rod connected to a high frequency power supply via a matching unit needs to be attached to a center of a bottom portion of the mounting table. FIGS. 15A and 15B are schematic views for explaining relation between an installation position of the power feed rod and an etching rate. FIG. 15A illustrates a gradient of the etching rate in the case of installing the power feed rod at a portion (right end portion) other than the center of the bottom portion of the mounting table by using contour lines. FIG. 15B illustrates as contour lines an inclination of the etching rate in the case of installing the power feed rod at the center of the bottom portion of the mounting table. As can be seen from FIGS. 15A and 15B, the uniformity of the etching rate obtained when the power feed rod is installed at the center of the bottom portion of the mounting table is improved compared to that of the etching rate obtained when the power feed rod is installed at the portion other than the center of the bottom portion of the mounting table. Therefore, the power feed rod needs to be installed at the center of the bottom portion of the mounting table. However, in the apparatus disclosed in Japanese Patent Application Publication No. 2004-63925, it is difficult to install the power feed rod at the central portion of the mounting table because the gas exhaust unit is disposed right below the mounting table to improve the distribution of flow of the reactant gas. Accordingly, the apparatus disclosed in Japanese Patent Application Publication No. 2004-63925 can improve the distribution of flow of the reactant gas but cannot improve the uniformity of the plasma processing. In other words, in the apparatus disclosed in Japanese Patent Application Publication No. 2004-63925, it is difficult to achieve both of uniform evacuation and uniform plasma processing.

In the apparatus disclosed in Japanese Patent Application Publication No. 2004-63925, it may be considered to bend the power feed rod and install the bent power feed rod at the center of the bottom portion of the mounting table in order to improve the uniformity of the plasma processing. However, the plasma processing may become inefficient as a length of the power feed rod is increased. For example, as shown in FIG. 16, if a length, a radius, a resistance component and a conductance of the power feed rod are respectively denoted by l, r, R and o and a frequency and a permeability are denoted by f and μ, respectively, a condition of R=(1/2πr)·(π1μ/σ)/2 is satisfied. Therefore, as the length l of the power feed rod is increased, the resistance component R is increased and this results in increase in the loss of supplied power. As described above, in the apparatus disclosed in Japanese Patent Application Publication No. 2004-63925, the attempt to improve the uniformity of the plasma processing may lead to decrease in the efficiency of the plasma processing.

### SUMMARY OF THE INVENTION

In this technical field, it is required to provide a plasma processing apparatus capable of adjusting a gap and achieving both of uniform evacuation and uniform plasma processing without decreasing efficiency of the plasma processing.

In accordance with an aspect of the present invention, there is provided a plasma processing apparatus including: a processing chamber; a mounting table provided in the processing chamber, the mounting table having a lower electrode; an upper electrode disposed to face the lower electrode; an extendable/retractable tube-shaped partition wall that connects the mounting table and a bottom wall of the processing chamber; a high frequency power supply configured to supply a high frequency power to the lower electrode; a power feed member provided in a space surrounded by the partition wall to connect the high frequency power supply and the mounting table; a driving frame extending from an outer side of a sidewall of the processing chamber to a lower side of the bottom wall of the processing chamber, and extending into the space surrounded by the partition wall to be connected to a bottom portion of the mounting table; a driving mechanism provided at the outer side of the sidewall of the processing chamber and serving to move the driving frame in an arrangement direction of the upper electrode and the lower electrode; a gas exhaust unit configured to depressurize an inside of the processing chamber; and a baffle plate provided in the processing chamber to partition the inside of the processing chamber into a processing space where the mounting table and the upper electrode are disposed and an annular gas exhaust space to which the gas exhaust unit is connected, wherein an annular gas exhaust passageway is defined below the annular gas exhaust space by the bottom wall and the sidewall of the processing chamber and the partition wall; and the gas exhaust unit communicates with the gas exhaust passageway through a gas exhaust port formed in the bottom wall of the processing chamber.

In the above plasma processing apparatus, the mounting table can be moved in the arrangement direction of the upper electrode and the lower electrode, i.e., the gap can be adjusted, by the extensible/contractible cylindrical partition wall, the driving frame and the driving mechanism. Further, the gap can be adjusted without providing the driving mechanism in the depressurized space because the driving mechanism is provided at the outside of the sidewall of the processing chamber and the driving frame is extended to the space surrounded by the partition wall so as to be connected to the mounting table. Accordingly, the effect of the components related to the driving on the evacuation can be reduced and, thus, the decrease in the uniformity of the evacuation can be prevented. In addition, the space surrounded by the partition wall is defined below the mounting table, so that the power feed rod can be inserted into the space and connected to the lower portion of the mounting table. Hence, a linear power feed rod, for example, can be installed at the center of the bottom portion of the mounting table and, thus, the power can be applied to the center of the mounting table by the power feed rod having a length as short as possible. As a result, both of the uniform evacuation and the uniform plasma processing can be achieved without deteriorating the efficiency of the plasma processing.

The sidewall of the processing chamber which defines the gas exhaust passageway may protrude outward compared to a sidewall of the processing chamber which defines the processing space. With such configuration, the volume of the gas exhaust passageway extending in the horizontal direction can be increased and the conductance of the fluid in the gas exhaust passageway can be increased. Therefore, the fluid can be easily moved in the horizontal direction and the effect of the installation position of the gas exhaust port on the efficiency and the uniformity of the evacuation can be reduced.

A maximum curvature of a horizontal cross section of the processing chamber which defines the gas exhaust passageway may be greater than a maximum curvature of a horizontal cross section of the processing chamber which defines the processing space. With such configuration, the volume of the gas exhaust passageway extending in the horizontal direction can be increased and the conductance of the fluid in the gas exhaust passageway can be increased. Accordingly, the fluid can be easily moved in the horizontal direction and the effect of the installation position of the gas exhaust port on the efficiency and the uniformity of the evacuation can be reduced.

The plasma processing apparatus may further include a cylindrical surrounding part provided at the mounting table to surround a side portion of the mounting table, wherein a center of a horizontal cross section of the gas exhaust port, when seen in the arrangement direction oft the upper electrode and the lower electrode, is located at an outer side of the sidewall of the processing chamber or at a position overlapped with the sidewall of the processing chamber which defines the processing space; and a radius of the horizontal cross section of the gas exhaust port is greater than a value obtained by subtracting a radius of a horizontal cross section of the cylindrical surrounding portion and the mounting table from a radius of a horizontal cross section of the processing space from a center of the mounting table. With such configuration, the decrease in the efficiency of the evacuation and the efficiency of the uniformity can be reduced without excessively increasing the apparatus width.

At the bottom wall of the processing chamber which defines the gas exhaust passageway, a first portion where the gas exhaust port is formed may protrude downward compared to a second portion separated from the gas exhaust port by a distance that is approximately a half of a circumference of the gas exhaust passageway. With such configuration, the volume of the gas exhaust space of the first portion side which is close to the gas exhaust port can become greater than the volume of the gas exhaust space of the second portion side which is farthest from the gas exhaust port. Therefore, a pressure difference between the gas exhaust space of the first portion side and the gas exhaust space of the second portion side can be reduced. Accordingly, the uniformity of the pressure distribution in the entire gas exhaust space can be improved.

The bottom wall of the processing chamber which defines the gas exhaust passageway may be inclined from the second portion toward the first portion. With such configuration, the uniformity of the pressure distribution in the entire gas exhaust space can be further improved.

A plurality of the driving mechanisms may be provided at the outer side of the sidewall of the processing chamber. With such configuration, the driving frame can be stably operated.

The driving mechanism may include: a driving source having a rotatable driving axis extending in the arrangement direction of the upper electrode and the lower electrode; a ball screw, having a screw shaft directly coupled to the driving axis, provided at the outer side of the sidewall of the processing chamber such that the screw shaft is coaxially disposed with the driving axis; a moving unit that is driven along the screw shaft and connected to the driving frame. With such configuration, the power of the driving source can be directly transmitted to the ball screw and the moving unit. Accordingly, the gap can be effectively adjusted and the apparatus width can be reduced compared to the case where the driving source and the ball screw are installed in the horizontal direction. As a result, the apparatus can be scaled down.

The plasma processing apparatus may further include a fixing member configured to fix the driving mechanism to the outer side of the sidewall of the processing chamber. With such configuration, the processing chamber and the mounting table can be relatively moved properly.

The plasma processing apparatus may further include a plate-shaped member that is bent such that one end portion and the other end portion are opposite to each other and provided in the gas exhaust space, wherein the one end portion is electrically connected to the mounting table and the other end portion is electrically connected to the sidewall of the processing chamber. With such configuration, the mounting table can be grounded even in the case of employing the gap adjusting unit.

### Effects of the Invention

As described above, the present invention provides the plasma processing apparatus capable of adjusting a gap and achieving both of uniform evacuation and uniform plasma processing without decreasing efficiency of the plasma processing.

### BRIEF DESCRIPTION OF THE DRAWINGS

FIG. 1 schematically shows a plasma processing apparatus in accordance with an embodiment of the present invention.

FIG. 2 is a schematic perspective view of driving mechanisms and a driving frame.

FIG. 3 is a schematic perspective view of a driving mechanism.

FIG. 4 is a detailed cross sectional view of a lower structure of the plasma processing apparatus in accordance with the embodiment of the present invention.

FIG. 5 is a horizontal cross sectional view taken along line V-V shown in FIG. 4.

FIG. 6 is a horizontal cross sectional view taken along line VI-VI shown in FIG. 4.

FIG. 7 is a horizontal cross sectional view taken along line VII-VII shown in FIG. 4.

FIG. 8 is a schematic diagram for explaining a formation position of a gas exhaust port.

FIGS. 9A and 9B are schematic diagrams for explaining evacuation flow in a gas exhaust space.

FIG. 10 is a schematic diagram for explaining conductances of an upper gas exhaust space and a gas exhaust passageway.

FIG. 11 is a schematic diagram for explaining an installation position of a ground member.

FIG. 12 is a perspective view of the ground member.

FIG. 13 is a block diagram for explaining motor control.

FIGS. 14A to 14C show simulation results for explaining correlation among the lower structure of the processing chamber, a flow velocity and a pressure.

FIGS. 15A and 15B are schematic diagrams for explaining relation between an installation position of a power feed rod and an etching rate.

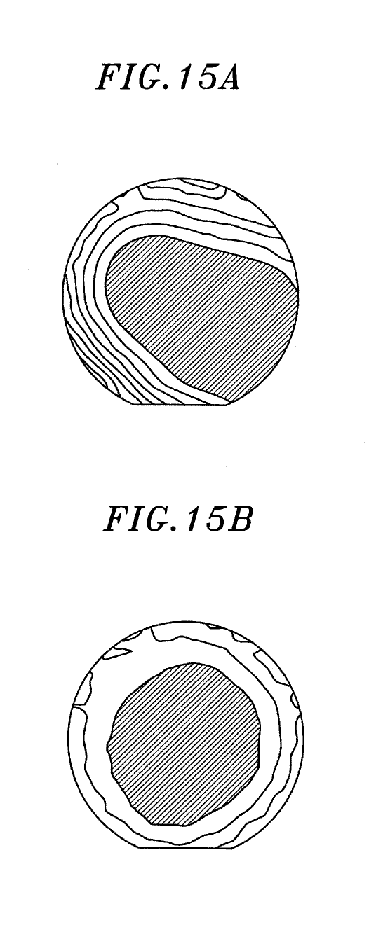

FIG. 16 is a schematic diagram for explaining relation between a resistance component and a length of the power feed rod.

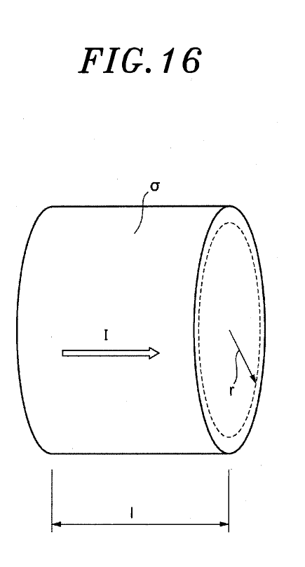

### DETAILED DESCRIPTION OF THE EMBODIMENTS

Hereinafter, embodiments of the present invention will be described in detail with reference to the accompanying drawings. Like reference numerals will be used for like or corresponding parts in the respective drawings.

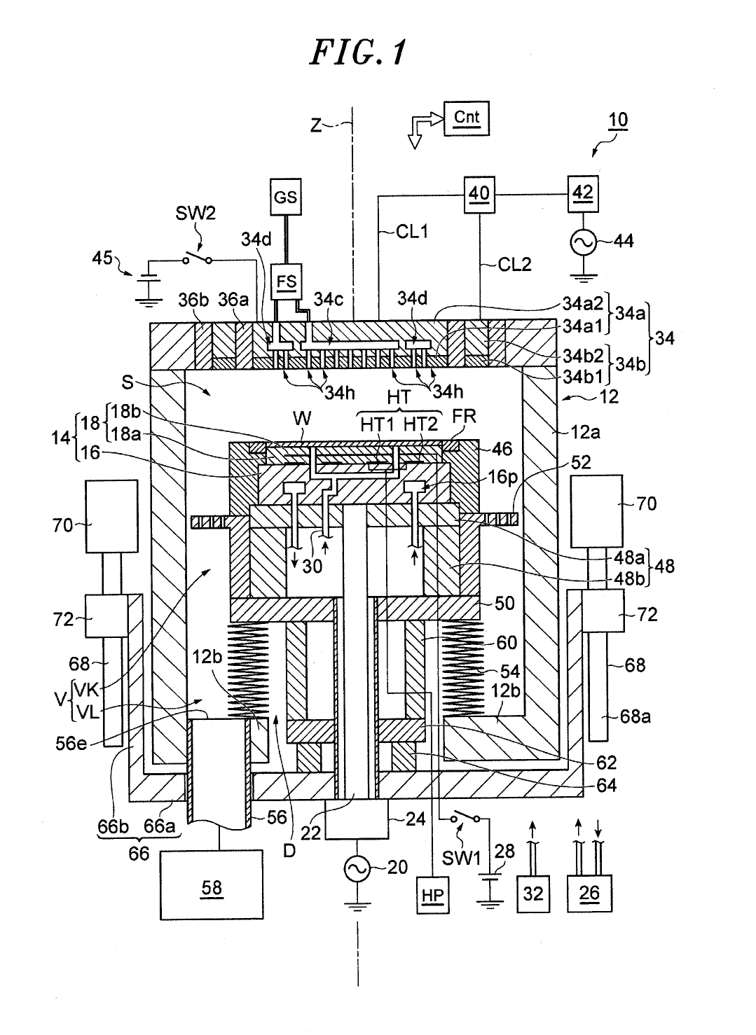

First, a plasma processing apparatus in accordance with an embodiment of the present invention will be described. FIG. 1 schematically shows a cross section of the plasma processing apparatus in accordance with the embodiment of the present invention. A plasma processing apparatus 10 shown in FIG. 1 is a parallel plate type plasma processing apparatus.

The plasma processing apparatus 10 includes a processing chamber 12. The processing chamber 12 defines a processing space S as its internal space. The processing chamber 12 has an approximately cylindrical sidewall 12a extending in a vertical direction along an axis Z. A gate valve that opens and closes a loading/unloading port for a target object (substrate) W to be processed is provided at the sidewall 12a.

A mounting table 14 is provided in the processing chamber 12. The mounting table 14 has a base 16 and an electrostatic chuck 18. The base 16 is formed in a substantially disc shape and has conductivity. The base 16 serves as a lower electrode and may be made of, e.g., aluminum.

A high frequency power supply 20 is connected to the base 16 via a power feed rod (power feed member) 22 and a matching unit 24. The high frequency power supply 20 applies a high frequency power having a predetermined high frequency, e.g., 2 MHz to 27 MHz, for ion attraction, i.e., a high frequency bias power, to the lower electrode, i.e., the base 16.

The electrostatic chuck 18 is provided on top of the base 16. The electrostatic chuck 18 is a substantially disc-shaped member and has an insulating layer 18a and a power feeding layer 18b. The insulating layer 18a is a film made of an insulator such as ceramic or the like. The power feeding layer 18b is a conductive film embedded in the insulating layer 18a. A DC power supply 28 is connected to the power feeding layer 18b via a switch SW1. When a DC voltage is applied from the DC power supply 28 to the power feeding layer 18b, Coulomb force is generated. The target object W is attracted and held on the electrostatic chuck 18 by the Coulomb force thus generated.

In the present embodiment, the base 16 may have a function of cooling the electrostatic chuck 18 by absorbing heat of the electrostatic chuck 18. Specifically, a coolant path 16p is formed in the base 16. A coolant inlet line and a coolant outlet line are connected to the coolant path 16p and also connected to a chiller unit 26. A coolant is circulated such that it is supplied from the chiller unit 26 to the coolant path 16p through the coolant inlet line and returns from the coolant path 16p to the chiller unit 26 through the coolant outlet line. The mounting table 14 can control temperatures of the base 16 and the electrostatic chuck 18 to a predetermined level by circulating a proper coolant, e.g., cooling water or the like, in the coolant path 16p.

In the present embodiment, a heater HT as a heating device may be provided between the electrostatic chuck 18 and the base 16. In the example shown in FIG. 1, the heater HT includes heaters HT1 and HT2. The heaters HT1 and HT2 are connected to a heater power supply HP. The heater HT1 extends in an annular shape so as to surround the axis Z. The heater HT1 heats a central region including the center of the target object W by heating a central region including the center of the electrostatic chuck 18. The heater HT2 extends in an annular shape so as to surround the axis Z at the outer side of the heater HT1. The heater HT2 heats an edge region including the edge of the target object W by heating a region at the outer side of the central region of the electrostatic chuck 18, i.e., an edge region including the edge of the electrostatic chuck 18. The heater HT can control a temperature of the target object W in each of a plurality of regions divided radially from the center of the target object W.

The plasma processing apparatus 10 may further include a gas supply line 30 and a heat transfer gas supply unit 32. The heat transfer gas supply unit 32 is connected to the gas supply line 30. The gas supply line 30 extends to the top surface of the electrostatic chuck 18 and extends in an annular shape on the top surface. The heat transfer gas supply unit 32 supplies a heat transfer gas, e.g., He gas, to a gap between the top surface of the electrostatic chuck 18 and the target object W.

The plasma processing apparatus 10 further includes an upper electrode 34. The upper electrode 34 is disposed above the lower electrode, i.e., the base 16, in the axis Z direction and faces the lower electrode with the processing space S therebetween. In the present embodiment, the upper electrode 34 may be provided so as to cover an upper opening of the processing chamber 12 as shown in FIG. 1.

In the present embodiment, the upper electrode 34 may include an inner electrode part 34a and an outer electrode part 34b. The inner electrode part 34a has an electrode plate 34a1 and an electrode holder 34a2. The electrode plate 34a1 is a conductive member. In the present embodiment, the electrode plate 34a1 is made of silicon. The electrode plate 34a1 has a substantially disc shape and is disposed such that a central axis thereof is coaxially disposed with the axis Z. The electrode holder 34a2 has conductivity and is made of, e.g., aluminum. The electrode holder 34a2 holds the electrode plate 34a1.

The outer electrode part 34b has an electrode plate 34b1 and an electrode holder 34b2. The electrode plate 34b1 is a conductive member. In the present embodiment, the electrode plate 34b1 is made of silicon. The electrode plate 34b1 extends in an annular shape about the Z-axis at the outer side of the electrode plate 34a1. The electrode holder 34b2 has conductivity and is made of, e.g., aluminum. The electrode holder 34b2 extends in an annular shape about the Z-axis at the outside of the electrode holder 34a2 and holds the electrode plate 34b1. An insulating member 36a is disposed between the outer electrode part 34b and the inner electrode part 34a. Another insulating member 36b is disposed between the outer electrode part 34b and the upper portion of the processing chamber 12.

In the present embodiment, the inner electrode part 34a may be connected to a power control circuit 40 through a wiring CL1. The outer electrode part 34b may be connected to the power control circuit 40 through a wiring CL2. A high frequency power supply 44 is connected to the power control circuit 40 via a matching unit 42. The high frequency power supply 44 supplies to the upper electrode 34 a high frequency power having a predetermined high frequency (e.g., 27 MHz or above) for plasma excitation.

In the present embodiment, a DC power supply 45 is connected to the inner electrode part 34a via a switch SW2. The DC power supply 45 applies a negative DC voltage to the inner electrode part 34a when the switch SW2 is closed.

In the plasma processing apparatus 10, the upper electrode 34 also serves as a shower head. In the present embodiment, a first buffer space 34c and a second buffer chamber 34d are formed in the electrode holder 34a2 of the inner electrode part 34a. The first buffer space 34c is provided at the central portion of the electrode support 34a2. The second buffer space 34d extends in an annular shape so as to surround the first buffer space 34c. The second buffer space 34d is separated from the first buffer space 34c. The first buffer space 34c and the second buffer space 34d are connected to a gas supply unit GS via a flow splitter FS. A plurality of gas injection holes 34h extends downward from the first buffer space 34c and the second buffer space 34d through the electrode holder 34a2 and the electrode plate 34a1 and communicates with the processing space S.

In the plasma processing apparatus 10, the gas supply unit GS, the flow splitter FS, the first buffer chamber 34c, the second buffer chamber 34d, and the gas injection holes 34h constitute a gas supply system. The gas supply unit GS may have a plurality of gas sources. The gas supply system supplies a gas selected among gases from the gas sources to the flow splitter FS at a flow rate controlled by a mass flow controller. The gas supplied to the flow splitter FS is supplied to the first buffer chamber 34c and the second buffer chamber 34d at a controlled distribution ratio by the flow splitter FS and injected into the processing space S through the gas injection holes 34h. The gas injection holes 34h connected to the first buffer chamber 34c are disposed so as to face the central region of the target object W. The gas injection holes 34h connected to the second buffer chamber 34d are disposed so as to face the edge region of the target object W. Therefore, in the plasma processing apparatus 10, it is possible to separately control a flow rate of a gas supplied to a space above the central region of the target object and a flow rate of a gas supplied to a space above the edge region of the target object W. Accordingly, a processing rate at the central region of the target object W and a processing rate at the edge region of the target object W can be separately controlled.

The plasma processing apparatus 10 includes a driving mechanism (gap adjusting mechanism) capable of a distance (gap) between the upper electrode 34 and the mounting table 14 including the lower electrode. In the embodiment shown in FIG. 1, the plasma processing apparatus 10 includes a driving mechanism capable of moving the mounting table 14 in the axis Z direction, i.e., in the vertical direction. Specifically, the plasma processing apparatus 10 includes a cylindrical surrounding part 46 surrounding the periphery (side portion) of the mounting table 14. A focus ring FR is provided on the top surface of the cylindrical surrounding part 46 so as to surround the electrostatic chuck 18.

The cylindrical surrounding part 46 and the base 16 are supported by a supporting table 48. The supporting table 48 includes a plate portion 48a and a cylindrical leg portion 48b. The plate portion 48a of the supporting table 48 is in contact with a lower end of the cylindrical surrounding portion 46 and a bottom surface of the base 16. The cylindrical surrounding portion 46 and the base 16 are fixed to the plate portion 48a. The leg portion 48b extends downward from a bottom surface of the plate portion 48a. The supporting table 48 is installed on the supporting plate 50 so that a lower end of the leg portion 48b becomes in contact with a top surface of the supporting plate 50. The supporting table 48 is fixed to the supporting plate 50.

A baffle plate 52 is provided between the supporting plate 50 and the cylindrical surrounding portion 46. The baffle plate 52 extends in an annular shape between the supporting table 48 and the sidewall 12a of the processing chamber 12. A plurality of through-holes is formed in the baffle plate 52. A cylindrical bellows (partition wall) 54, which is extendable/retractable, is provided between a peripheral portion of a bottom surface of the supporting plate 50 and the lower portion of the processing chamber 12. The bellows 54 defines, together with the sidewall 12a of the processing chamber 12, a gas exhaust space V communicating with the processing space S via the baffle plate 52 and separates the inner space of the processing chamber 12 such as the gas exhaust space V and the processing space S from the outside of the processing chamber 12. As will be described later, the gas exhaust space V includes an upper gas exhaust space VK corresponding to an upper portion of the gas exhaust space V and a gas exhaust passageway VL corresponding to a lower portion of the gas exhaust space V. A gas exhaust line 56 communicating with the gas exhaust passageway VL is provided at the bottom wall 12b of the processing chamber 12 through the gas exhaust port 56a. A gas exhaust unit 58 is connected to the gas exhaust line 56.

A leg portion 60, an annular plate 62, and a leg portion 64 are provided in a space D surrounded by the bellows 54. An upper end of the leg portion 60 is coupled to the bottom surface of the supporting plate 50. A lower end of the leg portion 60 is coupled to a top surface of the annular plate 62. An upper end of the leg portion 64 is coupled to a bottom surface of the annular plate 62. A lower end of the leg portion 64 is coupled to a plate portion 66a of a link 66.

As shown in FIG. 1, the link 66 includes the plate portion 66a and two columnar portions 66b. The plate portion 66a is provided below the bottom portion of the processing chamber 12. In the present embodiment, the aforementioned matching unit 24 is installed at the plate portion 66a. A through-hole extending in the axis Z direction is formed through the centers of the plate portion 66a, the supporting plate 50, and the plate portion 48a of the supporting table 48. The aforementioned power feed rod 22 extends to the base 16 through the through-hole of the plate portion 66a, an inner hole of the annular plate 62, the through hole of the supporting plate 50, and the through hole of the plate portion 48a of the supporting table 48.

The columnar portions 66b extend upward from the periphery of the plate portion 66a. The columnar portions 66b extend substantially in parallel to the sidewall 12a at the outside of the sidewall 12a. A feed mechanism (driving mechanism) using a ball screw is connected to the columnar portions 66b. Specifically, two screw shafts 68 extend substantially in parallel to the two columnar portions 66b at the outside of the sidewall 12a. The screw shafts 68 are connected to two motors 70, respectively. Two nuts (moving units) 72 are attached to the screw shafts 68, respectively. The two columnar portions 66b are coupled to the nuts 72, respectively.

Such a driving mechanism can move the nuts 72 in the axis Z direction, i.e., in the vertical direction, by rotating the motors 70. Due to the vertical movement of the nuts 72, the link 66, the leg portion 60, the annular plate 62 and the leg portion 64 are vertically moved as one unit. In other words, the leg portion 60, the annular plate 62, the leg portion 64 and the link 66 are connected to one another, thereby functioning as the driving frame. The mounting table 14 indirectly supported by the link 66 can be moved in the axis Z, i.e., in the vertically direction, by the vertical movement of the driving frame. The bellows 54 is extended/retracted by the vertical movement of the mounting table 14. As a result, the distance between the base 16, i.e., the lower electrode, and the upper electrode 34 can be controlled while ensuring airtightness in the processing space S.

In the present embodiment, the plasma processing apparatus 10 further includes a control unit Cnt. The control unit Cnt may be, e.g., a programmable computer. The control unit Cnt is connected to the switch SW1, the high frequency power supply 20, the matching unit 24, the high frequency power supply 44, the matching unit 42, a variable capacitor 40d, the switch SW2, the gas supply unit GS, the flow splitter FS, the heat transfer gas supply unit 32, the chiller unit 26, the heater power supply HP, the gas exhaust unit 58 and the motors 70.

The control unit Cnt operates by a program based on an input recipe and transmits a control signal. Based on control signals from the control unit Cnt, it is possible to control opening/closing of the switch SW1, power supply from the high frequency power supply 20, an impedance of the matching unit 24, power supply from the high frequency power supply 44, an impedance of the matching unit 42, a capacitance of the variable capacitor 40d, opening/closing of the switch SW1, selection of a gas among gases supplied from the gas supply unit GS and a flow rate thereof, a distribution ratio of the flow splitter FS, gas supply from the heat transfer gas supply unit 32, a flow rate and a temperature of a coolant from the chiller unit 26, power supply from the heater power supply HP, evacuation using the gas exhaust unit 58, and driving of the motors 70. The driving control of the motors 70 will be described in detail later.

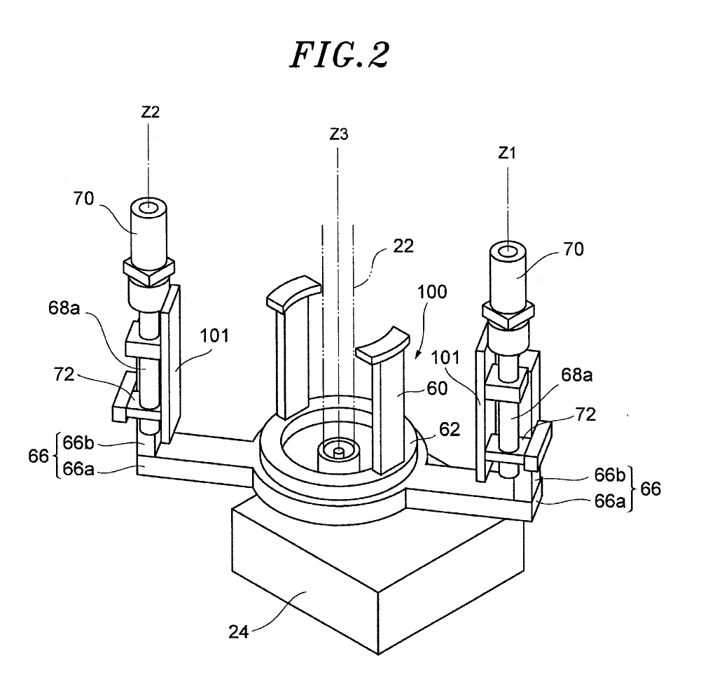

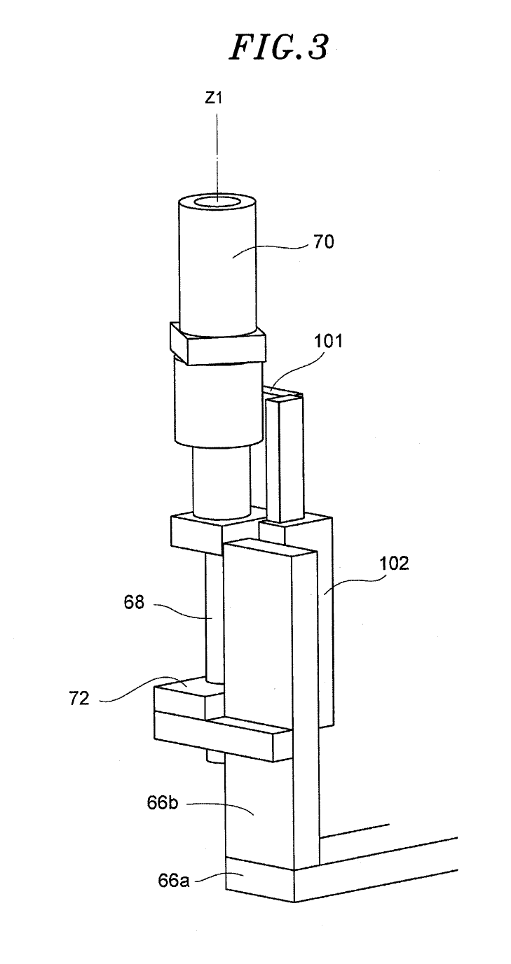

Next, the driving mechanisms and the driving frame of the plasma processing apparatus 10 will be described in detail. FIG. 2 is a perspective view of the driving mechanisms and the driving frame. FIG. 3 is a schematic perspective view of the driving mechanism. As shown in FIG. 2, the driving frame 100 is vertically movable by the two motors 70 serving as driving sources. Each of the driving mechanisms includes the motor 70, the ball screw having the screw shafts 68, and the nut 72. The driving mechanisms including the motors 70 are arranged opposite to each other with the power feed rod 22 therebetween. As shown in FIGS. 2 and 3, the two motors 70 have, as rotation axes (rotatable driving axis) thereof, axes Z1 and Z2 parallel to an axis Z3 (vertical direction) of the power feed rod 22. The screw shafts 68 are directly coupled to the motors 70 so that the driving force of the motors 70 is directly transmitted to the ball screws. The screw shafts 68 are coaxially disposed with the respective axes Z1 and Z2, respectively. In other words, the motors 70 and the screw shafts 68 are arranged such that the rotation axes of the motors 70 and the screw shafts 68 of the ball screws are coaxially disposed with the axes Z1 and Z2. The motors 70 and the screw shafts 68 are fixed to the outer side of the sidewall 12a of the processing chamber 12 by fixing members 101.

The nuts 72 attached to the screw shafts 68 are vertically moved along the axes Z1 and Z2. The two nuts 72 are connected to the two columnar portions 66b of the link 66. Further, guide members 102 for guiding the columnar portions 66b in the vertical direction are fixed to the fixing members 101. The guide members 102 are provided with rails (not shown) extending in the vertical direction. The columnar portions 66b are slidably attached to the rails. With such a configuration, when the nuts 72 are vertically moved, the link 66 is also vertically moved. In other words, the driving frame 100 formed by connecting the link 66, the leg portion 60 (see FIG. 1), the annular plate 62 and the leg portion 64 is vertically moved. The driving frame 100 is vertically moved while being supported at two points by two driving mechanisms. Since the driving frame 100 is supported at the two points, stable operation can be achieved.

The two columnar portions 66b forming the driving frame 100 are provided at the outer side of the sidewall 12a of the processing chamber 12. The plate portion 66a forming the driving frame 100 is provided at the outer side (lower side) of the bottom portion of the processing chamber 12. Therefore, the driving frame 100 extends from the outer side of the sidewall 12a of the processing chamber 12 to the outer side (lower side) of the bottom portion of the processing chamber 12. Further, the leg portion 60 (see FIG. 1), the annular plate 62 and the leg portion 64 forming the driving frame 100 are installed on the plate portion 66a to extend upward while surrounding the through hole formed at the plate portion 66a. Accordingly, the driving frame 100 extends from the outer side of the sidewall 12a of the processing chamber 12 to the outer side (lower side) of the bottom portion of the processing chamber 12 and also extends into the space D surrounded by the bellows 54. Further, the driving frame 100 is formed so as not to interfere with the linear power feed rod 22. Due to the shape of the driving frame 100, it is possible to adjust the gap without providing a driving mechanism in the depressurized space.

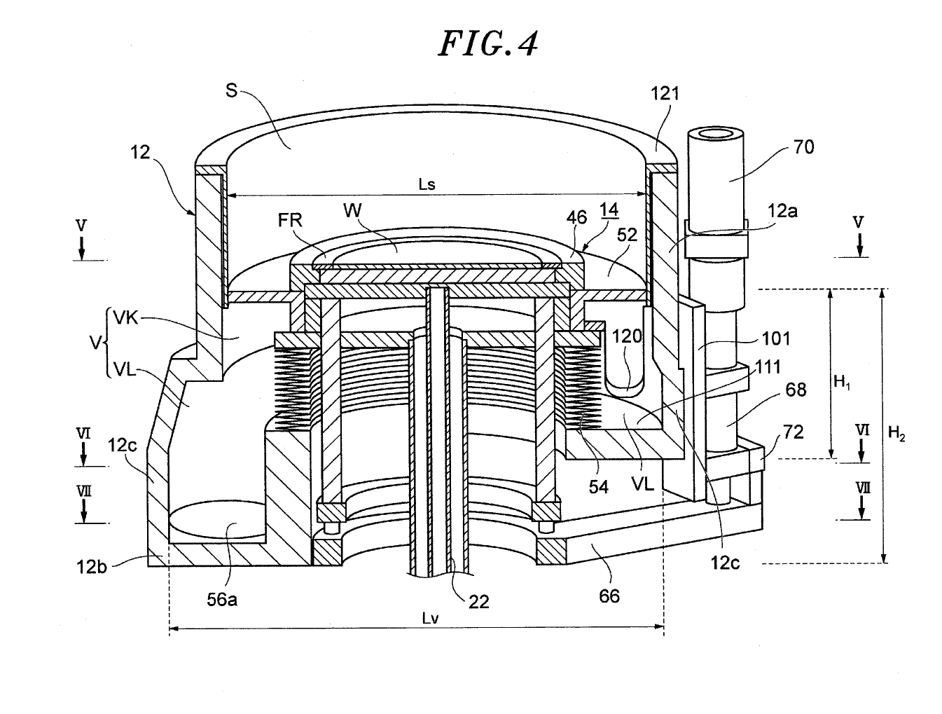

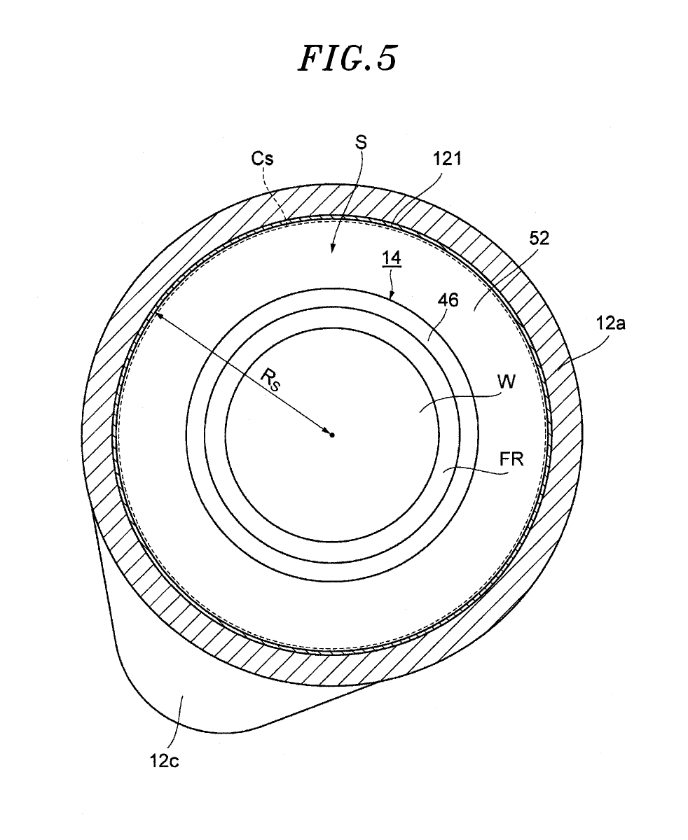

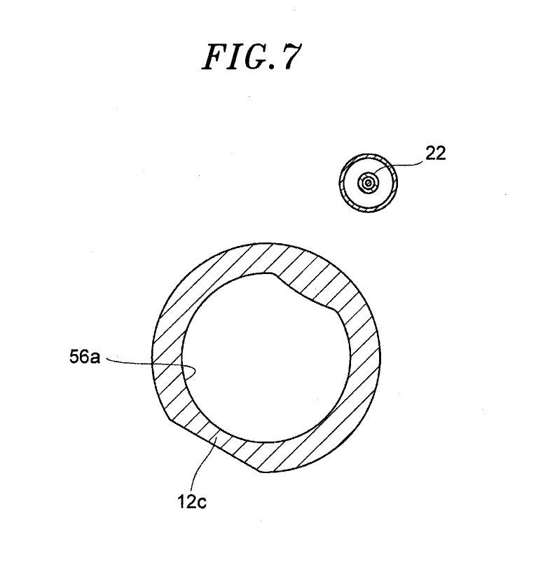

Next, the lower structure of the plasma processing apparatus 10 will be described in detail. FIG. 4 is a detailed cross sectional view of the lower structure of the plasma processing apparatus 10. FIGS. 5 to 7 are horizontal cross sectional views taken along lines V-V, VI-VI and VII-VII shown in FIG. 4, respectively. In FIGS. 5 to 7 for explaining the cross section of the processing chamber 12, components that are not related to the cross section of the processing chamber 12 are omitted.

As shown in FIG. 4, the power feed rod 22 is provided at the center of the bottom portion of the mounting table 14 and the power can be applied from the center of the mounting table. A deposition shield 121 is installed at an inner side of the sidewall 12a of the processing chamber 12 and connected to the supporting table 50 for supporting the mounting table 14 through a grounding member 120. This will be described in detail later. The driving mechanism having the motors 70 is installed at the outer side of the sidewall 12a of the processing chamber 12 by the fixing members 101 and supports the link 66. When the motors 70 are driven, the mounting table 14 and the baffle plate 52 are vertically moved. The baffle plate 52 divides the inner space of the processing chamber 12 into the processing space S and the gas exhaust space V. In other words, the volume of the gas exhaust space V is changed by the driving of the motors 70.

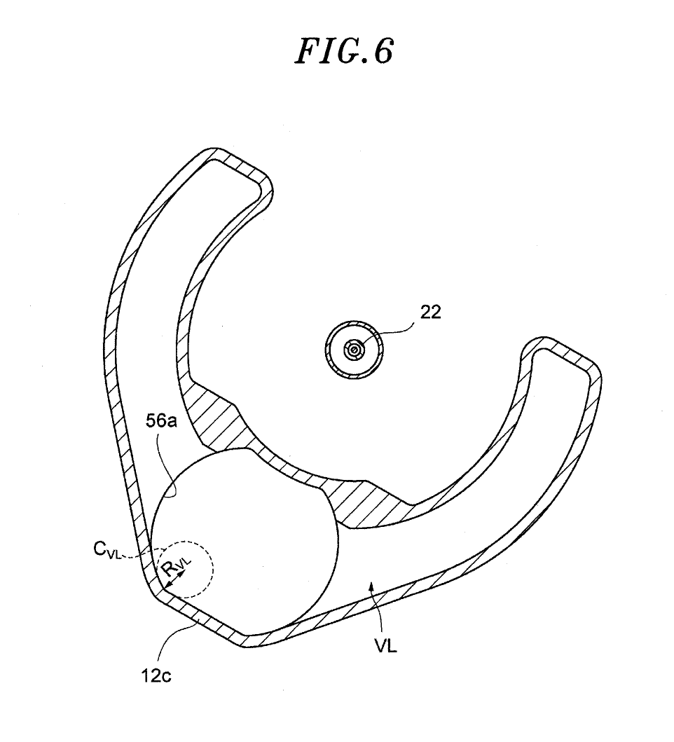

The upper gas exhaust space VK corresponding to the upper portion of the gas exhaust space V is defined by the sidewall 12a, the baffle plate 52, and the bellows 54. A diameter of the upper gas exhaust space VK is equal to a diameter L_{S} of the processing space S. Meanwhile, a lower sidewall 12c of the processing chamber 12 is expanded in a diametrically outward direction. For example, as shown in FIGS. 4 and 5, the lower sidewall 12c protrudes in the diametrically outward direction compared to the sidewall 12a. The annular gas exhaust passageway VL corresponding to the lower portion of the gas exhaust space V is defined by the lower sidewall 12c, the bottom wall 12b and the bellows 54. In other words, when it is assumed that the processing space S and the gas exhaust passageway VL have a circular horizontal cross section, a diameter L_{V} of the gas exhaust passageway VL is greater than a diameter L_{S} of the processing space S. The relation between the horizontal cross section of the processing space S and the horizontal cross section of the gas exhaust passageway VL can be expressed by using a maximum curvature. A curvature at a predetermined position of an outer periphery of a horizontal cross section is an inverse of a radius (curvature radius) of a maximum circle that comes into contact with that position. Therefore, a horizontal cross section having a maximum curvature has a steeply curved outer periphery. For example, as shown in FIG. 5, the processing space S has a substantially circular horizontal cross section, so that a maximum circle that comes into contact with the outer periphery of the horizontal cross section is a circle C_{S} having a uniform shape at any position of the outer periphery of the horizontal cross section. Thus, a minimum value of the curvature radius is a constant value R_{S}. Meanwhile, a part of the gas exhaust passageway VL has a shape that a part of an arc of a circle protrudes in a diametrically outward direction as shown in FIG. 6, so that a curvature radius of a maximum circle C_{VL} that comes into contact with that portion becomes minimum. Accordingly, the minimum value of the curvature radius becomes R_{LV}. In other words, the lower sidewall 12c is expanded such that a condition of R_{LV}<R_{S} is satisfied. The aforementioned relation expressed by the maximum curvature is (1/R_{LV})>(1/R_{S}). Hence, the lower sidewall 12c that defines the gas exhaust passageway VL is formed such that a maximum curvature of the horizontal cross section thereof becomes greater than a maximum curvature of the horizontal cross section of the sidewall 12a that defines the processing space S. In the present embodiment, the lower sidewall 12c of the gas exhaust passageway VL may be thinner than the sidewall 12a. In that case, the increase in the apparatus width can be suppressed while expanding the inner space.

The bottom wall 12b of the processing chamber 12 is inclined such that a portion where the gas exhaust port 56a is formed (first portion) is positioned at a lowermost level. For example, the first portion protrudes downward compared to a portion of the bottom wall 12b which is farthest from the first portion, i.e., a second portion 111 spaced from the gas exhaust port 56a by a distance of an approximately half of the circumference of the gas exhaust passageway VL. For example, on the assumption that a height from the baffle plate 52 to the second portion 111 is denoted by H₁ and a height from the baffle plate 52 to the first portion is denoted by H₂, a condition of H₂>H₁ is satisfied. In other words, the gas exhaust port 56a side has a larger depth than that of the opposite side of the gas exhaust port 56a. Here, a structure that is inclined from the second portion 111 toward the first portion in a stepwise manner is illustrated as an example. Due to this structure, an inner space becomes smaller toward a lower horizontal cross section as shown in FIGS. 5 to 7.

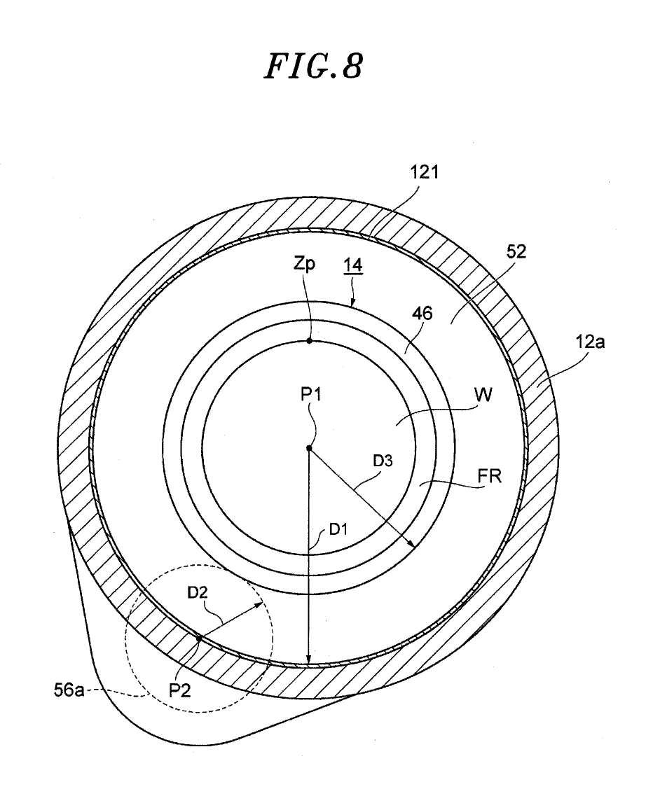

Next, the installation position of the gas exhaust port 56a will be described in detail. FIG. 8 is a horizontal cross sectional view of the processing chamber 12 which is taken in the same position as that in FIG. 5 and explains the installation position of the gas exhaust port 56a. As shown in FIG. 8, it is assumed that a center of the mounting table 14 is denoted by P1; a distance (radius) from the center P1 to the sidewall 12a is denoted by D1; and a distance (radius) from the center P1 to an outer periphery of the cylindrical surrounding portion 46 is denoted by D3. Further, a center of the gas exhaust port 56a is denoted by P2 and a radius of the gas exhaust port 56a is denoted by D2. In that case, the center P2 of the gas exhaust port 56a is located at a portion overlapped with the sidewall 12a when seen from the vertical direction. The gas exhaust port 56a is formed at a position where the radius D2 in the horizontal cross section of the gas exhaust port 56a becomes equal to a value obtained by subtracting the radius D3 of the horizontal cross section of the cylindrical surrounding portion 46 from the radius D1 of the horizontal cross section of the processing space 2 from the center of the mounting table 14. The center P2 of the gas exhaust port 56a may be located at a diametrically outer side of the sidewall 12a when seen from the vertical direction. The radius D2 of the horizontal cross section of the gas exhaust port 56a may be greater than or equal to the value obtained by subtracting the radius D3 of the horizontal cross section of the cylindrical surrounding portion 46 from the radius D1 of the horizontal cross section of the processing space 2 from the center of the mounting table 14.

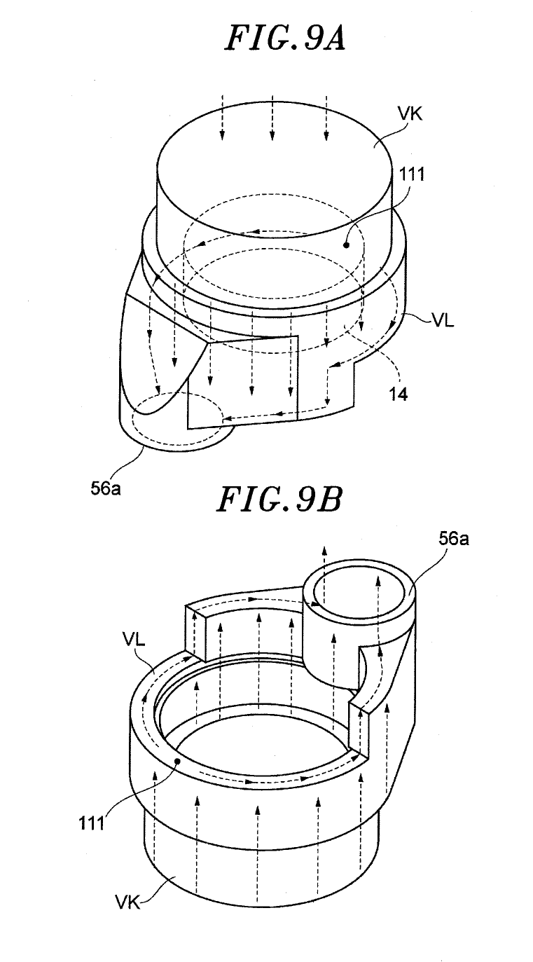

Next, the fluid flow in the lower portion of the processing chamber 12 will be described. FIGS. 9A and 9B schematically explain the evacuation flow in the gas exhaust space V. FIG. 9A shows only the gas exhaust space V of the processing chamber 12. FIG. 9B is a vertically reversed view of FIG. 9A. As shown in FIGS. 9A and 9B, a downflow directed to the bottom wall 12b is generated in the upper gas exhaust space VK. The downflow does not affect the installation position of the gas exhaust port 56a and a flow velocity thereof is substantially uniform at any location. Meanwhile, a horizontal flow (directed along the bottom wall 12b of the processing chamber 12) is generated in the gas exhaust passageway VL. In other words, there is generated an air flow inclined toward the gas exhaust port 56a from the second portion 111 farthest from the first portion where the gas exhaust port 56a is formed.

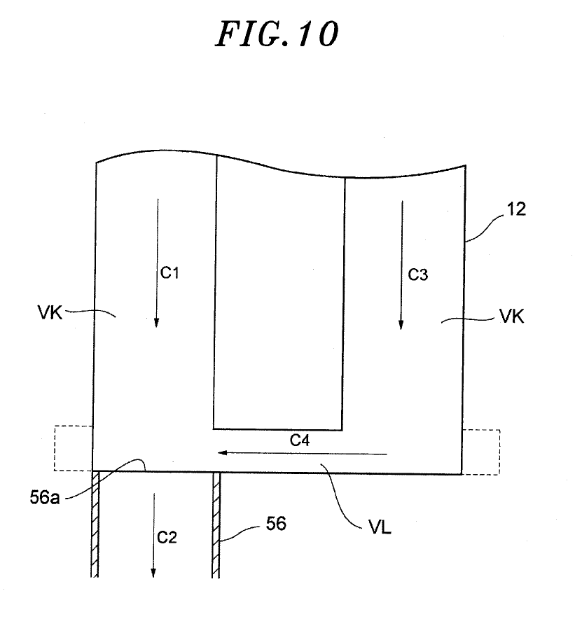

Since the gas exhaust port 56a is formed at a position separated from the bottom portion of the mounting table 14, a distance to the gas exhaust port 56a is different between the first portion where the gas exhaust port 56a is formed and the second portion 111 farthest from the first portion. Hence, the uniformity of the evacuation may deteriorate. In the plasma processing apparatus 10 of the present embodiment, the deterioration of the uniformity of the evacuation is prevented by increasing the diameter of the gas exhaust passageway VL. Hereinafter, this will be described in detail with reference to FIG. 10. FIG. 10 is a schematic diagram for explaining conductances of the upper gas exhaust space VK and the gas exhaust passageway VL. As shown in FIG. 10, a gas exhaust route 1 directed from the upper gas exhaust space VK to the gas exhaust port 56a directly and a gas exhaust route 2 directed from the upper gas exhaust space VK to the gas exhaust port 56a via the gas exhaust passageway VL exist in the gas exhaust space V. On the assumption that the conductances of the upper gas exhaust space VK are denoted by C1 and C3; the conductance of the gas exhaust passageway VL is denoted by C4; and the conductance of the gas exhaust line 56 is denoted by C2, the conductance of the gas exhaust route 1 becomes C1+C2 and the conductance of the gas exhaust route 2 becomes C3+C4+C2. Since the conductances C1 and C3 of the upper gas exhaust space VK can be considered to be substantially the same, the difference between the gas exhaust route 1 and the gas exhaust route 2 is the conductance C4 of the gas exhaust passageway VL. By increasing the diameter of the bottom portion that defines the gas exhaust passageway VL as indicated by dotted lines in the drawing, the conductance C4 of the gas exhaust passageway VL can be increased. When the conductance C4 of the gas exhaust passageway VL is increased, the resistance (difficulty in fluid flow) of the gas exhaust passageway VL is decreased. In other words, the degree of fluid flow in the gas exhaust route 1 and that in the gas exhaust route 2 become substantially the same. In the plasma processing apparatus 10 of the present embodiment, the difference in the fluid resistance between the gas exhaust route 1 and the gas exhaust route 2 is reduced by increasing the space volume of the part of the gas exhaust passageway VL. Accordingly, the deterioration of the uniformity of the evacuation is suppressed.

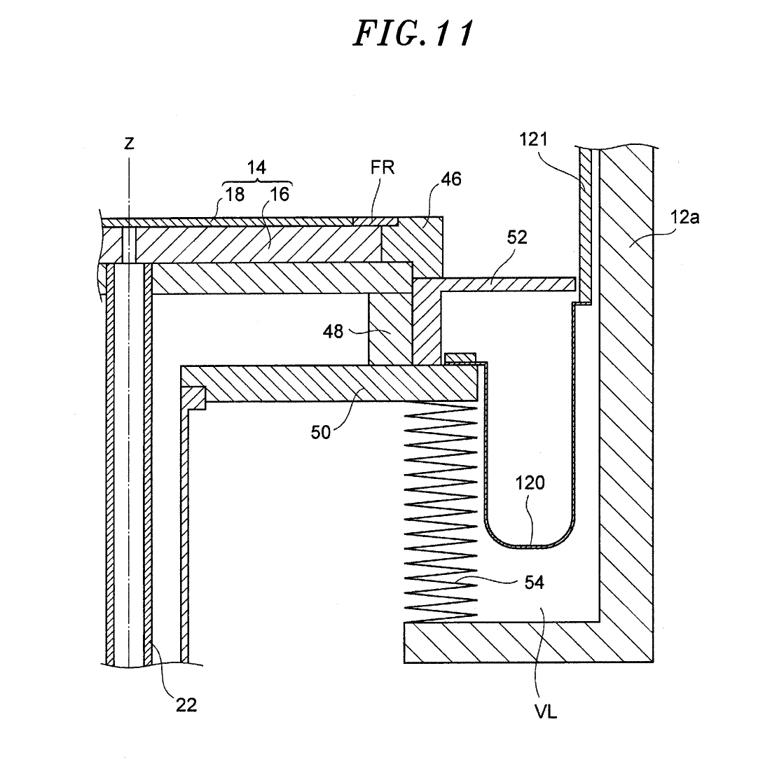

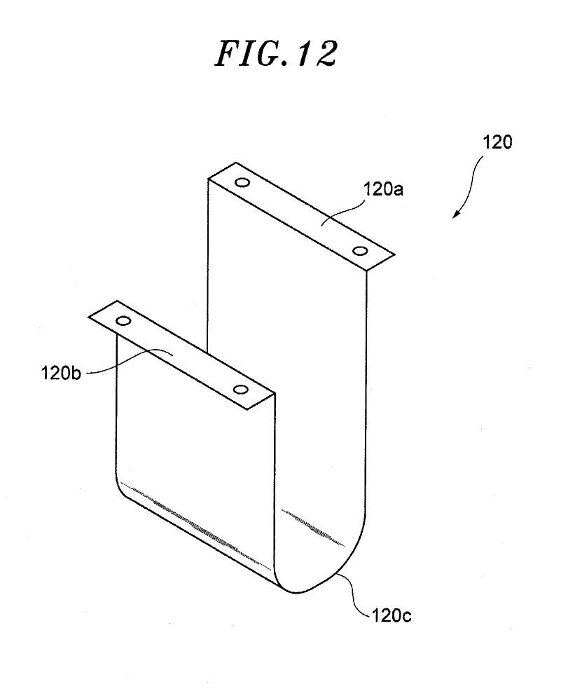

Next, the grounding of the gap adjusting unit will be briefly described. FIG. 11 is a schematic diagram for explaining an installation position of the grounding member 120. FIG. 12 is a perspective view of the grounding member 120. As shown in FIGS. 11 and 12, the grounding member 120 that is a plate-shaped member is bent such that one end portion and the other end portion are opposite to each other. The one end portion of the grounding member 120 is electrically connected to the supporting plate 50 for supporting the mounting table 14 and the other end portion of the grounding member 120 is electrically connected to the deposition shield 121. The grounding member 120 is installed by, e.g., screw fixation. With such a configuration, a high frequency current of the power applied to the mounting table 14, for example, can flow to the ground through the grounding member 120, not through the bellows 54 having a large impedance, so that the stable plasma generation can be realized even when the gap adjusting unit is employed. Since the grounding member 120 is a bent plate-shaped member, it can properly deal with the vertical movement of the mounting table 14.

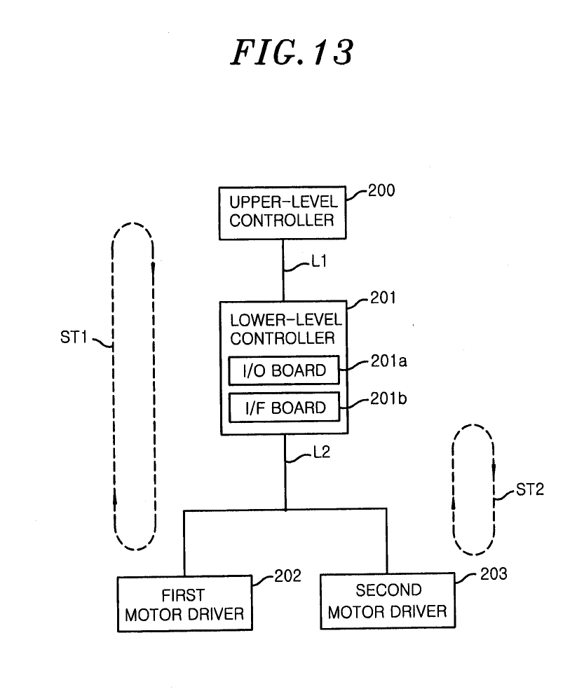

Next, the driving control of the motors 70 will be briefly described. FIG. 13 is a block diagram showing a configuration of the control system (control unit Cnt) for controlling the two motors 70. As shown in FIG. 13, the control system includes an upper-level controller 200, a lower-level controller 201, a first motor driver 202 and a second motor driver 203. The upper-level controller 200, the lower-level controller 201, the first motor driver 202 and the second motor driver 203 may be constituted by a computer system having, as hardware, a CPU, a main storage unit such as a RAM and a ROM, an auxiliary storage unit such as a hard disk or the like, a communication interface that is a data transmitting/receiving device such as a network card or the like.

The upper-level controller 200 that is a top-level unit for conducting overall gap adjusting control can communicate with the lower-level controller 201 via a line L1. The lower-level controller 201 can communicate with the first motor driver 202 and the second motor driver 203 via a line L2.

The upper-level controller 200 transmits a control command that instructs a gap size or the like to the lower-level controller 201. Further, the upper-level controller 200 monitors status (including completion of position determination and abnormality detection) of all devices that are subordinate to the upper-level controller 200 (ST1). The upper-level controller 200 monitors the status of the devices at an interval of, e.g., 500 msec.

The lower-level controller 201 includes, as units for conducting overall control of two motors 70, an I/O board 201a and an I/F board 201b. The I/O board 201a controls the communication with the upper-level controller 200. In other words, the I/O board 201a receives the control command from the upper-level controller 200 and transmits a position determination completion signal or an abnormality detection signal to the upper-level controller 200. The I/O board 201a generates commands related to synchronization and position control of the motors 70 and monitors positions and torques of the motors 70 (ST2). The I/O board 201a monitors the positions and the torques of the motors 70 at an interval of, e.g., 20 msec. The I/F board 201b controls the communication with the first motor driver 202 and the second motor driver 203. In other words, the I/F board 201b receives the position determination completion signal, the abnormality detection signal, and the information on the positions or the torques of the motors 70 from the first motor driver 202 and the second motor driver 203 and transmits the commands generated by the I/O board 201a to the first motor driver 202 and the second motor driver 203. The first motor driver 202 and the second motor driver 203 drive the motors 70 based on the commands generated by the I/O board 201a and transmits the position determination completion signal, the abnormality detection signal, and the information on the positions or the torques of the motors 70 to the I/F board 201b, if necessary.

In the control system, the lower-level controller 201 that is close to a driver of a device, not the upper-level controller 200, monitors operation information of the device such as positions or torques at an interval shorter than the monitoring interval of the upper-level controller 200. Accordingly, improper operation of the motors 70 can be detected at an early stage.

The plasma processing apparatus 10 of the present embodiment can move the mounting table 14 in an arrangement direction of the upper electrode and the lower electrode by using the extendable/retractable cylindrical bellows 54, the driving frame 100 and the driving mechanism. In other words, the gap can be adjusted. Further, the gap can be adjusted without providing the driving mechanism in the depressurized space because the driving mechanism is provided at the outer side of the sidewall 12a of the processing chamber 12 and the driving frame 100 extends to the space D surrounded by the bellows 54 so as to be connected to the mounting table 14. Accordingly, the effect of the components related to the driving on the evacuation can be reduced, and the deterioration of the uniformity of the evacuation can be prevented. In addition, the space D surrounded by the bellows 54 is defined below the mounting table 14, so that the power feed rod 22 can be inserted into the space D and connected to the lower portion of the mounting table 14. Hence, a linear power feed rod 22, for example, can be installed at the center of the bottom portion of the mounting table 14 and, thus, the power can be applied to the center of the mounting table 14 by the power feed rod 22 having a length as short as possible. As a result, both of the uniform evacuation and the uniform plasma processing can be realized without deteriorating the efficiency of the plasma processing.

In the plasma processing apparatus 10 of the present embodiment, the lower sidewall 12c of the processing chamber 12 which defines the gas exhaust passageway VL protrudes outward compared to the sidewall 12a of the processing chamber 12 which defines the processing space S. With this configuration, the curvature of the horizontal cross section of the processing chamber 12 which defines the gas exhaust passageway VL is greater than the curvature of the horizontal cross section of the processing chamber 12 which defines the processing space S. Therefore, the volume of the gas exhaust passageway VL extending in the horizontal direction can be increased and the conductance of the fluid in the gas exhaust passageway VL can be increased. Accordingly, the fluid can be easily moved in the horizontal direction and the effect of the installation position of the gas exhaust port 56a on the efficiency and the uniformity of the evacuation can be reduced.

In the plasma processing apparatus 10 of the present embodiment, at the bottom wall 12b of the processing chamber 12 which defines the gas exhaust passageway VL, the first portion where the gas exhaust port 56a is provided may protrude downward compared to the second portion 111 spaced from the gas exhaust port 56a by a distance that is approximately a half of the circumference of the gas exhaust passageway VL. With such a configuration, the volume of the gas exhaust space of the first portion side which is close to the gas exhaust port 56a can become greater than the volume of the gas exhaust space of the second portion 111 side which is farthest from the gas exhaust port 56a. Therefore, a pressure difference between the gas exhaust space of the first portion side and the gas exhaust space of the second portion 111 can be reduced. Accordingly, the uniformity of the pressure distribution in the entire gas exhaust space can be improved.

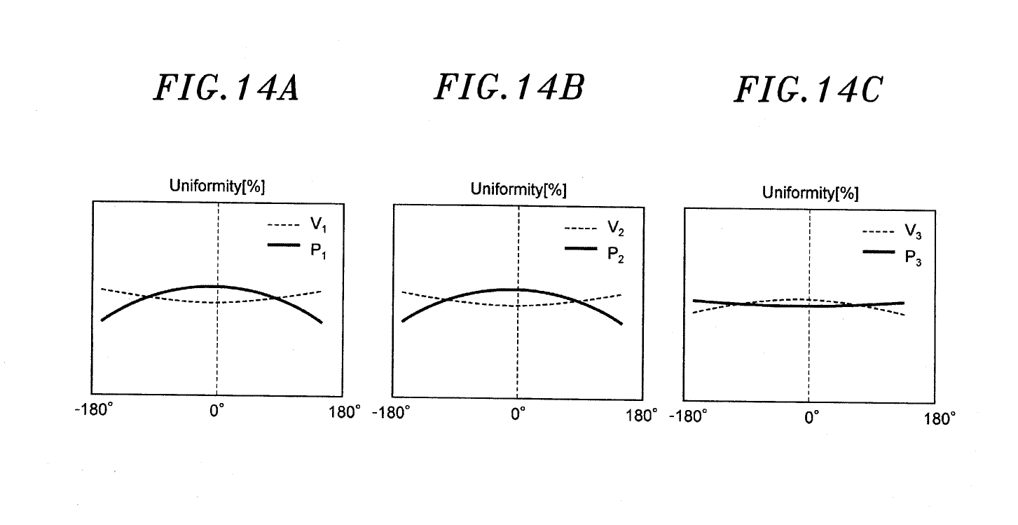

FIGS. 14A to 14C show simulation results for explaining correlation among the lower structure of the processing chamber, a flow velocity and a pressure. The horizontal axis of the graph represents an entire circumference (from −180° to +180°, the right-side circumference being a positive angle) of the boundary between the target object W and the focus ring RF in the case of setting a reference point Zp (see FIG. 8) on the boundary to 0°. The vertical axis of the graph represents a difference from average uniformity. FIG. 14A shows a result of simulation of a flow velocity V₁ and a pressure P₁ in the case of using the processing chamber 12 in an initial state. FIG. 14B shows a result of simulation of a flow velocity V₂ and a pressure P₂ in the case of increasing a volume of a stepped portion of the bottom wall 12b of the processing chamber 12 (in the case of moving the stepped portion toward the second portion) compared to the case shown in FIG. 14A. FIG. 14C shows a result of simulation of a flow velocity V₃ and a pressure P₃ in the case of increasing the volume of the stepped portion of the bottom wall 12b of the processing chamber 12 as in the case shown in FIG. 14B and expanding the lower sidewall 12c of the processing chamber 12. The comparison between FIGS. 14A and 14B demonstrates that the distribution of the flow velocity and the pressure are improved in the case of increasing the volume of the stepped portion of the bottom wall 12b of the processing chamber 12, i.e., in the case of increasing the volume of the evacuation side (the case shown in FIG. 14B). Further, the comparison between FIGS. 14B and 14C demonstrates that the distribution of the flow velocity and the pressure are improved in the case of expanding the lower sidewall 12c of the processing chamber 12 (the case shown in FIG. 14C). In other words, excellent uniformity of evacuation is obtained due to the shape of the processing chamber 12 of the plasma processing apparatus 10 of the present embodiment.

In the plasma processing apparatus 10 of the present embodiment, the gas exhaust port 56a is formed at a portion where the radius D2 of the horizontal cross section is equal to a value obtained by subtracting the radius D3 of the horizontal cross section of the mounting table 14 and the cylindrical surrounding portion 46 from the radius D1 of the horizontal cross section of the processing space S from the center P1 of the mounting table 14. Accordingly, the deterioration of the efficiency and the uniformity of the evacuation can be suppressed without excessively increasing the apparatus width.

In the plasma processing apparatus 10 of the present embodiment, the driving force of the motors 70 can be directly transmitted to the ball screws and the nuts 72, so that the gap can be effectively adjusted. Moreover, the apparatus can be scaled down by reducing the apparatus width compared to the case where the motors 70 and the ball screws are arranged in the horizontal direction.

While the embodiments of the present invention have been described, the present invention may be various modified without being limited to the above embodiments. For example, the plasma processing apparatus of the above embodiment employs a configuration that the mounting table serving as the lower electrode is moved in the axis Z direction. However, a configuration that the upper electrode 34 is moved in the axis Z direction may be employed.

The above embodiments have described an example in which two motors 70 are provided. However, the number of the motors 70 may be one or more than three.

### DESCRIPTION OF REFERENCE NUMERALS

10 plasma processing apparatus
12 processing chamber
12a sidewall
14 mounting table
16 base (lower electrode)
18 electrostatic chuck
20 high frequency power supply LF
22 power feed rod (power feed member)
24 matching unit
26 chiller unit
28 DC power supply for electrostatic chuck
32 heat transfer gas supply unit
34 upper electrode
34a inner electrode part
34a1 electrode plate
34a2 electrode holder
34b outer electrode part
34b1 electrode plate
34b2 electrode holder
34c first buffer space
34d second buffer space
34h gas injection hole
40 power control circuit
40d variable capacitor
42 matching unit
44 high frequency power supply HF
45 DC power supply
52 baffle plate
54 bellows
56a gas exhaust port
60 leg portion (driving frame)
62 annular plate (driving frame)
64 leg portion (driving frame)
66 link (driving frame)
68 screw shaft
70 motor
72 nut (moving unit)
101 fixing member
111 second portion
FR focus ring
FS flow splitter
GS gas supply unit
HP heater power supply
HT HT1, HT2 heaters
Cnt control unit
W target object
S processing space
V gas exhaust space
VK upper gas exhaust space
VL gas exhaust passageway
D space surrounded by bellows

1. A plasma processing apparatus comprising:
a processing chamber;
a mounting table provided in the processing chamber, the mounting table having a lower electrode;
an upper electrode disposed to face the lower electrode;
an extendable/retractable tube-shaped partition wall that connects the mounting table and a bottom wall of the processing chamber;
a high frequency power supply configured to supply a high frequency power to the lower electrode;
a power feed member provided in a space surrounded by the partition wall to connect the high frequency power supply and the mounting table;
a driving frame extending from an outer side of a sidewall of the processing chamber to a lower side of the bottom wall of the processing chamber, and extending into the space surrounded by the partition wall to be connected to a bottom portion of the mounting table;
a driving mechanism provided at the outer side of the sidewall of the processing chamber and serving to move the driving frame in an arrangement direction of the upper electrode and the lower electrode;
a gas exhaust unit configured to depressurize an inside of the processing chamber; and
a baffle plate provided in the processing chamber to partition the inside of the processing chamber into a processing space where the mounting table and the upper electrode are disposed and an annular gas exhaust space to which the gas exhaust unit is connected,
wherein an annular gas exhaust passageway is defined below the annular gas exhaust space by the bottom wall and the sidewall of the processing chamber and the partition wall; and
the gas exhaust unit communicates with the gas exhaust passageway through a gas exhaust port formed in the bottom wall of the processing chamber.

2. The plasma processing apparatus of claim 1, wherein the sidewall of the processing chamber includes a first sidewall portion which defines the gas exhaust passageway and a second sidewall portion which defines the processing space, the first sidewall portion protruding outward compared to the second sidewall portion.

3. The plasma processing apparatus of claim 1, wherein the sidewall of the processing chamber includes a first sidewall portion which defines the gas exhaust passageway and a second sidewall portion which defines the processing space, and a maximum curvature of a horizontal cross section of the first sidewall portion is greater than a maximum curvature of a horizontal cross section of the second sidewall portion.

4. The plasma processing apparatus of claim 1, further comprising a cylindrical surrounding part provided at the mounting table to surround a side portion of the mounting table,
wherein a center of a horizontal cross section of the gas exhaust port, when seen in the arrangement direction of the upper electrode and the lower electrode, is located at an outer side of the sidewall of the processing chamber or at a position overlapped with the sidewall of the processing chamber which defines the processing space; and
a radius of the horizontal cross section of the gas exhaust port is greater than a value obtained by subtracting a radius of a horizontal cross section of the cylindrical surrounding portion and the mounting table from a radius of a horizontal cross section of the processing space from a center of the mounting table.

5. The plasma processing apparatus of claim 1, wherein at the bottom wall of the processing chamber which defines the gas exhaust passageway, a first portion where the gas exhaust port is formed protrudes downward compared to a second portion separated from the gas exhaust port by a distance that is approximately a half of a circumference of the gas exhaust passageway.

6. The plasma processing apparatus of claim 5, wherein the bottom wall of the processing chamber which defines the gas exhaust passageway is inclined from the second portion toward the first portion.

7. The plasma processing apparatus of claim 1, wherein a plurality of the driving mechanisms is provided at the outer side of the sidewall of the processing chamber.

8. The plasma processing apparatus of claim 1, wherein the driving mechanism includes:
a driving source having a rotatable driving axis extending in the arrangement direction of the upper electrode and the lower electrode;
a ball screw, having a screw shaft directly coupled to the driving axis, provided at the outer side of the sidewall of the processing chamber such that the screw shaft is coaxially disposed with the driving axis;
a moving unit that is driven along the screw shaft and connected to the driving frame.

9. The plasma processing apparatus of claim 1, further comprising a fixing member configured to fix the driving mechanism to the outer side of the sidewall of the processing chamber.

10. The plasma processing apparatus of claim 1, further comprising a plate-shaped member that is bent such that one end portion and the other end portion are opposite to each other and provided in the gas exhaust space, wherein the one end portion is electrically connected to the mounting table and the other end portion is electrically connected to the sidewall of the processing chamber.

11. The plasma processing apparatus of claim 2, wherein a maximum curvature of a horizontal cross section of the first sidewall portion is greater than a maximum curvature of a horizontal cross section of the second sidewall portion.
